(19) United States
(12) Patent Application Publication
(10) Pub. No.: US 2026/0213727 A1
(43) Pub. Date: Jul. 23, 2026

(54) SURFACE ACOUSTIC WAVE RESONATOR

(71) Applicant: WiPAM, Inc., Seongnam-si, Gyeonggi-do (KR)

(72) Inventors: Dae Kyu YU, Seoul (KR); Kyoung Joon MIN, Seongnam-si, Gyeonggi-do (KR); Kyung Oh KIM, Seoul (KR)

(73) Assignee: WiPAM, Inc., Seongnam-si, Gyeonggi-do (KR)

(21) Appl. No.: 19/142,967

(22) PCT Filed: Oct. 23, 2023
(86) PCT No.: PCT/KR2023/016457

§ 371 Date: Jun. 25, 2025

(30) Foreign Application Priority Data
Dec. 26, 2022 (KR) 10-2022-0184690

(51) Int. Cl. H03H 9/02; H03H 9/25; H03H 9/64

(52) U.S. Cl. CPC H03H 9/02842; H03H 9/25; H03H 9/64

(57) ABSTRACT

A surface acoustic wave resonator includes: a piezoelectric substrate; an IDT electrode unit provided on the piezoelectric substrate, the IDT electrode unit being configured to perform at least one of conversion of an electrical signal into a surface acoustic wave on the piezoelectric substrate and conversion of the surface acoustic wave into an electrical signal; a reflection unit disposed in a propagation direction of the surface acoustic wave generated from the IDT electrode unit, the reflection unit being configured to reflect the surface acoustic wave to the IDT electrode unit, wherein the reflection unit comprises a plurality of electrically separated reflectors having different aperture lengths.

### TECHNICAL FIELD

The present invention relates to a surface acoustic wave resonator used in a filter that converts an electrical signal into a surface acoustic wave of a piezoelectric material using the piezoelectric effect of the piezoelectric material and converts the converted acoustic wave back into an electrical signal.

### BACKGROUND ART

With development of mobile communication devices such as smartphones and tablets, there is an increasing need to improve the performance of surface acoustic wave elements and devices such as surface acoustic wave resonators used therein and filters using the same.

FIG. 1 shows the structure of a conventional surface acoustic wave resonator (SAW resonator). Such a conventional surface acoustic wave resonator includes an interdigital transducer configured such that metal electrodes are continuously arranged parallel to each other on a piezoelectric substrate 10 made of a piezoelectric material, i.e., an IDT structure 20. When an alternating signal voltage is applied to the IDT 20, an electric field is generated between the electrodes in the IDT, and the surface of the piezoelectric substrate is deformed by the piezoelectric effect of the piezoelectric substrate, whereby a surface acoustic wave (SAW) propagates in both directions of the IDT.

The surface acoustic wave generated on the piezoelectric substrate 10 by the IDT 20 may perform a function of a bandpass filter that passes a frequency component that is in synchronization with the frequency of the surface acoustic wave and attenuates the remaining signal while being converted back to an electrical signal by an output electrode in the IDT or another IDT disposed adjacent thereto.

At this time, reflectors 31 and 32 that form gratings made of metal thin film may be provided around the IDT 20 on the piezoelectric substrate 10 to reflect the surface acoustic wave generated by the IDT 20, thereby reducing loss.

However, as mobile communication devices such as smartphones increasingly operate at higher frequencies and over broader bands in recent years, a structure that can be integrated while achieving performance, such as high speed and high coupling, of surface acoustic wave resonators is requested, and as more frequency bands are required to be supported with the evolution of mobile communication standard generations, miniaturization and integration are becoming inevitable requirements.

Accordingly, in order to integrate surface acoustic wave resonators or surface acoustic wave filters having various frequency bands, it is increasingly necessary to reduce the insertion loss of each filter so as to reduce the influence of adjacent bands, to improve the attenuation characteristics in a stop band, and to minimize ripple in the stop band, thereby reducing the influence or interference between bands. However, the conventional reflector structure of the surface acoustic wave resonator has limitations, and there is a need to develop a further improved surface acoustic wave resonator to reduce insertion loss and ripple.

### PRIOR ART DOCUMENTS

Korean Patent Application Publication No. 2006-0041296

Japanese Patent Application Publication No. 2016-152494

Japanese Registered Patent Publication No. 6620036

### DISCLOSURE

### Technical Problem

It is an object of the present invention to provide a surface acoustic wave resonator capable of reducing the insertion loss in a pass band, improving the attenuation characteristics in a stop band, and reducing ripple in the stop band by improving the characteristics of a reflector while not changing the size of a conventional surface acoustic wave resonator or reducing the size of the conventional surface acoustic wave resonator.

### Technical Solution

A surface acoustic wave resonator according to an embodiment of the present invention includes a piezoelectric substrate, an IDT electrode unit provided on the piezoelectric substrate, the IDT electrode unit being configured to perform at least one of conversion of an electrical signal into a surface acoustic wave on the piezoelectric substrate and conversion of the surface acoustic wave into an electrical signal, a reflection unit disposed in a propagation direction of the surface acoustic wave generated from the IDT electrode unit, the reflection unit being configured to reflect the surface acoustic wave to the IDT electrode unit, wherein the reflection unit includes a plurality of electrically separated reflectors having different aperture lengths.

The reflection unit may include a first reflection unit disposed on the piezoelectric substrate at one end of the IDT electrode unit, the first reflection unit including a plurality of reflectors having different aperture lengths, and a second reflection unit disposed on the piezoelectric substrate at the other end of the IDT electrode unit, the second reflection unit including a plurality of reflectors having different aperture lengths.

The IDT electrode unit may include at least one of a one-port IDT electrode having a plurality of input fingers and a plurality of output fingers and a two-port IDT electrode including an input IDT electrode and an output IDT electrode disposed spaced apart from each other by a predetermined distance.

The first reflection unit may include a first main reflector disposed adjacent to the one end of the IDT electrode unit, the first main reflector having the same aperture length as the IDT electrode unit, the first main reflector being configured to reflect the surface acoustic wave from the IDT electrode unit to the IDT electrode unit, and at least one first sub-reflector disposed behind the first main reflector, the at least one first sub-reflector having a smaller aperture length than the first main reflector, and the second reflection unit may include a second main reflector disposed adjacent to the other end of the IDT electrode unit, the second main reflector having the same aperture length as the IDT electrode unit, the second main reflector being configured to reflect the surface acoustic wave from the IDT electrode unit to the IDT electrode unit, and at least one second sub-reflector disposed behind the second main reflector, the at least one second sub-reflector having a smaller aperture length than the second main reflector.

The first reflection unit may include a first main reflector disposed adjacent to the one end of the IDT electrode unit, the first main reflector being configured to reflect the surface acoustic wave from the IDT electrode unit to the IDT electrode unit, the first main reflector being electrically grounded, and at least one first sub-reflector disposed behind the first main reflector, the at least one first sub-reflector being electrically separated from the first main reflector, and the second reflection unit may include a second main reflector disposed adjacent to the other end of the IDT electrode unit, the second main reflector being configured to reflect the surface acoustic wave from the IDT electrode unit to the IDT electrode unit, the second main reflector being electrically grounded, and at least one second sub-reflector disposed behind the second main reflector, the at least one second sub-reflector being electrically separated from the second main reflector.

The first main reflector and the first sub-reflector of the first reflection unit may be electrically separated from each other while the first main reflector may be electrically grounded, and the second main reflector and the second sub-reflector of the second reflection unit may be electrically separated from each other while the second main reflector may be electrically grounded.

The first sub-reflector and the second sub-reflector may have the same aperture length or different aperture lengths.

The aperture length of the reflector disposed on the piezoelectric substrate at the end thereof in the propagation direction of the surface acoustic wave toward one side of the IDT electrode unit and the aperture length of the reflector disposed on the piezoelectric substrate at the end thereof in the propagation direction of the surface acoustic wave toward the other side of the IDT electrode unit may be different from each other.

### Advantageous Effects

A surface acoustic wave resonator according to the present invention has the effect that a reflection unit including a plurality of reflectors having different aperture lengths is provided by improving the structure of a reflector of a conventional surface acoustic wave resonator while not changing the size of the conventional surface acoustic wave resonator or reducing the size of the conventional surface acoustic wave resonator, thereby reducing the insertion loss in a pass band according to frequency response, improving the attenuation characteristics in a stop band, and reducing ripple in the stop band.

### DESCRIPTION OF DRAWINGS

FIG. 1 is a view showing a conventional surface acoustic wave resonator.

FIG. 2 is a view showing a surface acoustic wave resonator according to an embodiment of the present invention, wherein the surface acoustic wave resonator includes a one-port IDT electrode structure and a reflection unit.

FIG. 3 is a view showing a surface acoustic wave resonator according to another embodiment of the present invention, wherein the surface acoustic wave resonator includes a two-port IDT electrode structure and a reflection unit.

FIG. 4 is a graph showing the insertion loss characteristics of a surface acoustic wave filter designed with the surface acoustic wave resonator according to the embodiment of the present invention and the insertion loss characteristics of a conventional surface acoustic wave filter for comparison.

FIG. 5 is a graph showing a stop band of a frequency response curve of each of the surface acoustic wave filter designed with the surface acoustic wave resonator according to the embodiment of the present invention and the conventional surface acoustic wave filter.

FIG. 6 is an enlarged view of region A of the stop band on the graph shown in FIG. 4.

### BEST MODEL

A surface acoustic wave resonator according to the present invention will be described in detail with reference to the drawings.

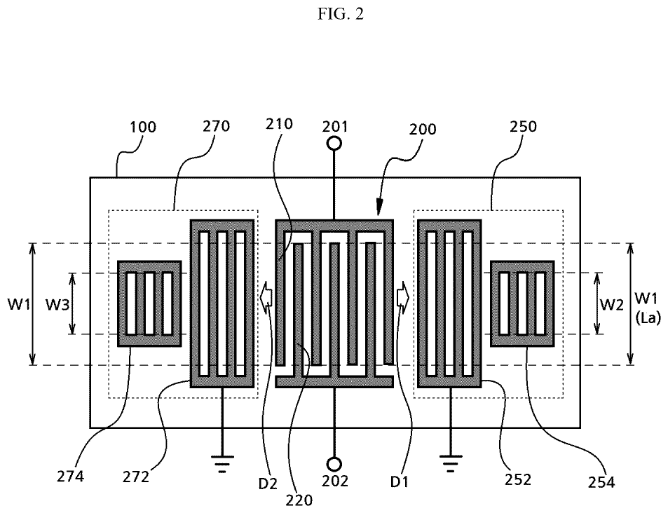

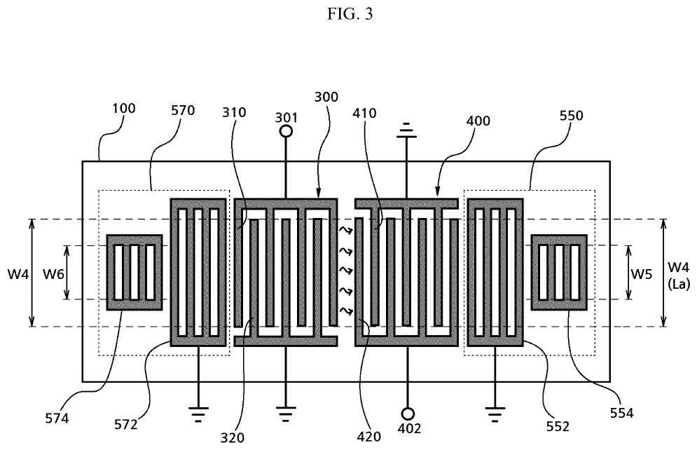

FIGS. 2 and 3 are views showing the configurations of embodiments of a surface acoustic wave resonator according to the present invention, wherein FIG. 2 is a view showing the configuration of a surface acoustic wave resonator having a one-port IDT electrode and FIG. 3 is a view showing the configuration of a surface acoustic wave resonator having a two-port IDT electrode.

As shown in FIGS. 2 and 3, the surface acoustic wave resonator according to the present invention includes a piezoelectric substrate 100 made of a material having a piezoelectric effect and an IDT electrode unit 200 or 300 and 400 provided on the piezoelectric substrate 100 to convert an electrical signal into a surface acoustic wave on the piezoelectric substrate 100, to convert a surface acoustic wave on the piezoelectric substrate 100 into an electrical signal, or to perform the above two conversion operations.

The surface acoustic wave resonator according to the present invention includes a reflection unit formed by modifying the structure of a reflector used in a conventional surface acoustic wave resonator in order to reduce insertion loss, ripple, and the like.

The reflection unit is disposed on the piezoelectric substrate in the propagation direction of the surface acoustic wave generated from the IDT electrode unit and to reflect the surface acoustic wave to the IDT electrode unit.

The reflection unit may be applied to a surface acoustic wave resonator having a one-port IDT electrode as shown in FIG. 2, and may also be applied to a surface acoustic wave resonator having a two-port IDT electrode as shown in FIG. 3.

Since the reflection unit is disposed in the propagation direction of the surface acoustic wave generated from the IDT electrode unit, it is preferable for the reflection unit to be provided at each of one end and the other end of the IDT electrode unit.

FIG. 2 shows an embodiment of a surface acoustic wave resonator having a one-port IDT electrode 200 as the IDT electrode unit, wherein reflection units 250 and 270 are provided on both sides of the IDT electrode 200, respectively.

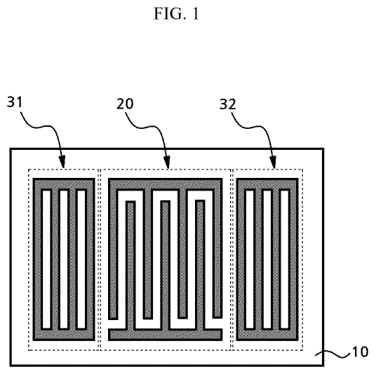

As shown in FIG. 1, the one-port IDT electrode 200 includes a plurality of metal electrodes having a comb structure. That is, a plurality of fingers is separated into an input end 201 and an output end 202, and a plurality of input fingers 210 and a plurality of output fingers 220 are alternately disposed. When an electrical signal is applied through the input end 201, a surface acoustic wave is generated on the piezoelectric substrate 100 by an electric field between the plurality of input fingers 210 and the plurality of output fingers 220, and the surface acoustic wave is converted into an electrical signal and output to the output end 202.

At this time, the surface acoustic wave generated from the IDT electrode 200 propagates in both directions, i.e., in direction D1 and direction D2, as shown in FIG. 1.

In this way, the reflecting units on both sides reflect the surface acoustic wave propagating in both directions, thereby reducing loss.

Conventionally, a reflector configured to reflect the surface acoustic wave propagating from the IDT electrode is constituted by a single electrical mass, but such a reflector configuration is limited in reducing the loss of the acoustic wave. The reflection unit of the present invention has improved performance by configuring the reflection unit to include a plurality of electrically separated reflectors having different aperture lengths, rather than being constituted by a single electrical mass having a plurality of electrodes.

As shown in FIG. 2, the reflection unit may include a first reflection unit 250 disposed on the piezoelectric substrate 100 at one end of the IDT electrode 200 and including a plurality of reflectors 252 and 254 having different aperture lengths and a second reflection unit 270 disposed on the piezoelectric substrate 100 at the other end of the IDT electrode 200 and including a plurality of reflectors 272 and 274 having different aperture lengths.

Each of the reflection units 250 and 270 may include a plurality of reflectors. As shown in FIG. 2, the reflection unit 250 or 270 may include a main reflector 252 or 272 disposed adjacent to the IDT electrode unit 200 and at least one sub-reflector 254 or 274 disposed on a side thereof.

That is, the first reflection unit 250 may include a first main reflector 252 disposed adjacent to one end of the IDT electrode unit 200 and having the same aperture length W1 as the IDT electrode unit 200 and at least one first sub-reflector 254 disposed behind the first main reflector 252 and having a smaller aperture length W2 than the first main reflector.

In addition, the second reflection unit 270 may include a second main reflector 272 disposed adjacent the other end of the IDT electrode unit 200 and having the same aperture length W1 as the IDT electrode unit 200 and at least one second sub-reflector 274 disposed behind the second main reflector 272 and having a smaller aperture length W3 than the second main reflector.

The characteristics of the surface acoustic wave generated from the IDT electrode 200 may be significantly influenced by the aperture length and a plurality of parameters such as the thickness and width of each of the fingers 210 and 220, the distance between the electrodes, period, and pitch.

The aperture length of the IDT electrode is the length of the section in which the finger electrodes 210 and 220 overlap each other, which may be the section in which an effective acoustic wave is generated. In FIG. 2, the aperture length of the IDT electrode 200 is denoted by La.

The reflection unit also has a plurality of gratings, i.e., rod-shaped electrodes, and has an aperture length corresponding to the aperture length La of the IDT electrode. As shown in FIG. 2, The first main reflector 252 of the first reflection unit 250 may have the same aperture length W1 as the aperture length La of the IDT electrode, and at least one first sub-reflector 254 disposed behind the first main reflector may have a smaller aperture length W2 than the first main reflector 252.

In addition, the second main reflector 272 of the second reflection unit 270 may have the same aperture length W1 as the aperture length La of the IDT electrode, and at least one second sub-reflector 274 disposed behind the second main reflector may have a smaller aperture length W3 than the second main reflector 272.

That is, the first reflection unit 250 may include a plurality of reflectors 252 and 254 disposed such that the aperture length of the front reflector is greater than the aperture length of the rear reflector (W1>W2), and the second reflection unit 270 may include a plurality of reflectors 272 and 274 disposed such that the aperture length of the front reflector is greater than the aperture length of the rear reflector (W1>W3).

At this time, the aperture length W2 of the first sub-reflector 254 and the aperture length W3 of the second sub-reflector 274 may be equal to each other or may be different from each other, which may be set as W2=W3 or W2/W3 at the time of design depending on the characteristics of the surface acoustic wave.

That is, the aperture length of the reflector disposed on the piezoelectric substrate at the end thereof in the propagation direction of the surface acoustic wave toward one side of the IDT electrode unit and the aperture length of the reflector disposed on the piezoelectric substrate at the end thereof in the propagation direction of the surface acoustic wave toward the other side of the IDT electrode unit may be different from each other.

In addition, as shown in FIG. 2, the first main reflector 252 and the first sub-reflector 254 of the first reflection unit 250 may be electrically separated from each other rather than forming a single electrically connected mass, and the first main reflector 252 adjacent to the IDT electrode, which is a reflector that directly receives most of the surface acoustic wave, is electrically grounded.

Similarly, the second main reflector 272 and the second sub-reflector 274 of the second reflection unit 270 may be electrically separated from each other rather than forming a single electrically connected mass, and the first main reflector 272 adjacent to the IDT electrode, which is a reflector that directly receives most of the surface acoustic wave, is electrically grounded.

In this case, the first sub-reflector 254 and the second sub-reflector 274 may be configured not to be grounded, and each of the first sub-reflector 254 and the second sub-reflector 274 may include a plurality of reflectors having the same aperture length, wherein the plurality of reflectors may have gradually decreasing aperture lengths.

That is, the first reflection unit 250 may include one first main reflector 252 and one first sub-reflector 254, or may include one first main reflector 252 and a plurality of first sub-reflectors 254, wherein the reflectors are preferably electrically separated from each other.

In addition, the second reflection unit 270 may include one second main reflector 272 and one second sub-reflector 274, or may include one second main reflector 272 and a plurality of second sub-reflectors 274, wherein the reflectors are preferably electrically separated from each other.

A surface acoustic wave resonator according to another embodiment of the present invention will be described with reference to FIG. 3.

It was previously described that the reflection unit of the surface acoustic wave resonator according to the embodiment of the present invention can be applied to a surface acoustic wave resonator having a one-port IDT electrode, and the reflection unit may also be applied to a surface acoustic wave resonator having a two-port IDT electrode, as shown in FIG. 3.

FIG. 3 shows an embodiment of a surface acoustic wave resonator having a two-port IDT electrode 300 and 400 as the IDT electrode unit, wherein reflection units 550 and 570 are provided on both sides of the IDT electrode unit 300 and 400, respectively.

As shown in FIG. 3, the two-port IDT electrode may be separated into an input IDT electrode 300 and an output IDT electrode 400.

The input IDT electrode 300 is configured such that a plurality of input fingers 310 and a plurality of output fingers 320 are alternately disposed, wherein the input fingers 310 are connected to an input end 301 and the output fingers 320 are grounded. In addition, the output IDT electrode 400 is configured such that a plurality of input fingers 410 and a plurality of output fingers 420 are alternately disposed, wherein the input fingers 410 are grounded and the output fingers 420 are connected to an output end 402. When an electrical signal is applied to the input IDT electrode 300 via the input end 301, the electrical signal is converted into a surface acoustic wave and propagates, and the surface acoustic wave is converted back into an electrical signal at the output IDT electrode 400 and output to the output end 402.

At this time, the surface acoustic wave generated from each of the IDT electrodes 300 and 400 may propagate in both directions, and the reflection units on both sides may reflect the surface acoustic wave propagating in both end directions to reduce loss.

Here, as shown in FIG. 3, the reflection unit includes a first reflection unit 550 disposed on the piezoelectric substrate 100 at one end of the IDT electrode unit 300 and 400 and including a plurality of reflectors 552 and 554 having different aperture lengths and a second reflection unit 570 disposed on the piezoelectric substrate 100 at the other end of the IDT electrode unit 300 and 400 and including a plurality of reflectors 572 and 574 having different aperture lengths.

The first reflection unit 550 and the second reflection unit 570 of the surface acoustic wave resonator having the two-port IDT electrode structure shown in FIG. 3 may have substantially the same configuration as the reflection units of the surface acoustic wave resonator having the one-port IDT electrode structure shown in FIG. 2.

That is, the first reflection unit 550 may include a first main reflector 552 disposed adjacent to one end of the IDT electrode unit 300 and 400 and having the same aperture length W4 as the aperture length La of the IDT electrode unit 300 and 400 and at least one first sub-reflector 554 disposed behind the first main reflector 552 and having a smaller aperture length W5 than the first main reflector.

In addition, the second reflection unit 570 may be configured to include a second main reflector 572 disposed adjacent to the other end of the IDT electrode unit 300 and 400 and having the same aperture length W4 as the IDT electrode unit 300 and 400 and at least one second sub-reflector 574 disposed behind the second main reflector 572 and having a smaller aperture length W6 than the second main reflector.

That is, the first reflection unit 550 may include a plurality of reflectors 552 and 554 disposed such that the aperture length of the front reflector is greater than the aperture length of the rear reflector (W4>W5), and the second reflection unit 570 may include a plurality of reflectors 572 and 574 disposed such that the aperture length of the front reflector is greater than the aperture length of the rear reflector (W4>W6).

At this time, the aperture length W5 of the first sub-reflector 554 and the aperture length W6 of the second sub-reflector 574 may be equal to each other or may be different from each other, which may be set as W5=W6 or W5≠W6 at the time of design depending on the characteristics of the surface acoustic wave.

That is, the aperture length of the reflector disposed on the piezoelectric substrate at the end thereof in the propagation direction of the surface acoustic wave toward one side of the IDT electrode unit and the aperture length of the reflector disposed on the piezoelectric substrate at the end thereof in the propagation direction of the surface acoustic wave toward the other side of the IDT electrode unit may be different from each other.

In addition, as shown in FIG. 3, the first main reflector 552 and the first sub-reflector 554 of the first reflection unit 550 may be electrically separated from each other rather than forming a single electrically connected mass, and the first main reflector 552 adjacent to the IDT electrode, which is a reflector that directly receives most of the surface acoustic wave, is electrically grounded.

Similarly, the second main reflector 572 and the second sub-reflector 574 of the second reflection unit 570 may be electrically separated from each other rather than forming a single electrically connected mass, and the first main reflector 572 adjacent to the IDT electrode, which is a reflector that directly receives most of the surface acoustic wave, is electrically grounded.

In this case, the first sub-reflector 554 and the second sub-reflector 574 may be configured not to be grounded, and each of the first sub-reflector 554 and the second sub-reflector 574 may include a plurality of reflectors having the same aperture length, wherein the plurality of reflectors may have gradually decreasing aperture lengths.

That is, the first reflection unit 550 may include one first main reflector 552 and one first sub-reflector 554, or may include one first main reflector 552 and a plurality of first sub-reflectors 554, wherein the reflectors are preferably electrically separated from each other.

In addition, the second reflection unit 570 may include one second main reflector 572 and one second sub-reflector 574, or may include one second main reflector 572 and a plurality of second sub-reflectors 574, wherein the reflectors are preferably electrically separated from each other.

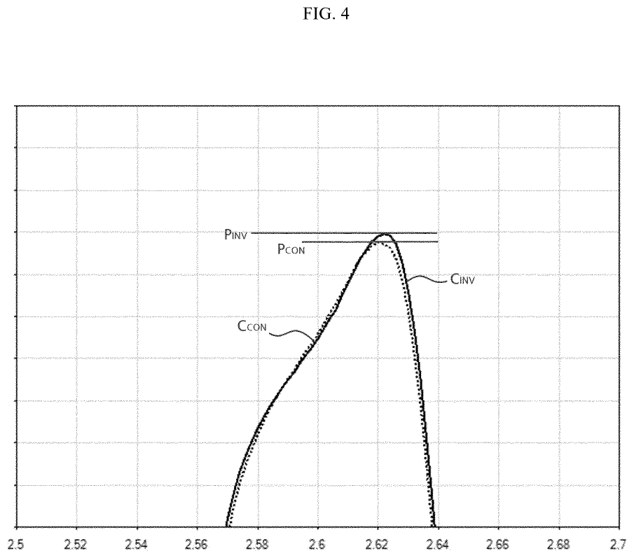

Improvement in performance of the surface acoustic wave resonator according to the embodiment of the present invention will be described with reference to FIGS. 4 to 6.

In the surface acoustic wave resonator according to each of the embodiments shown in FIGS. 2 and 3, the configuration of the reflection unit is adopted, whereby the insertion loss of a pass band may be reduced, the attenuation characteristics of a stop band may be improved, and ripple in the stop band may be reduced, compared to a conventional surface acoustic wave resonator having a simple form of reflector.

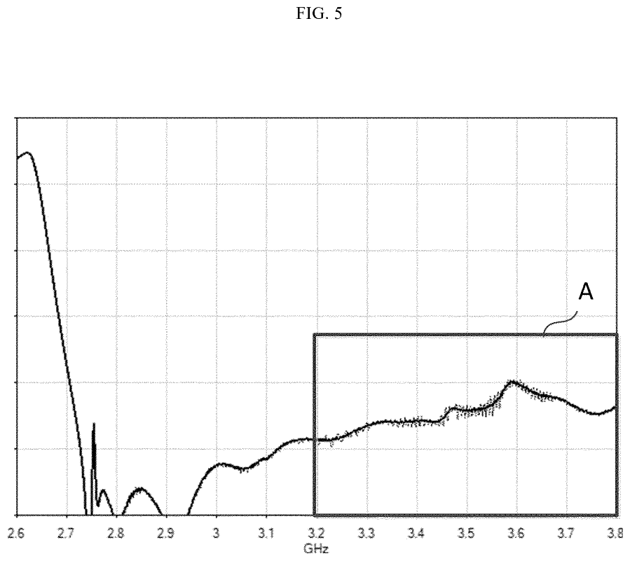

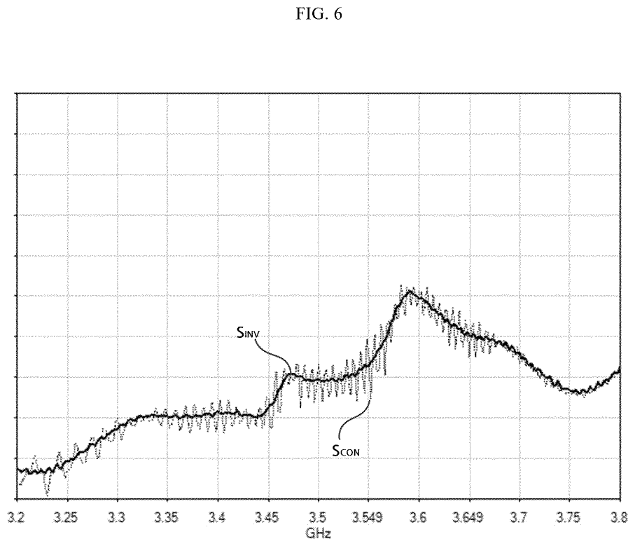

FIG. 4 shows that a surface acoustic wave filter designed with the surface acoustic wave resonator according to the embodiment of the present invention has improved insertion loss characteristics compared to a conventional surface acoustic wave filter, and FIGS. 5 and 6 show that the surface acoustic wave filter designed with the surface acoustic wave resonator according to the embodiment of the present invention has improved attenuation characteristics and reduced ripple in the stop band of a frequency response curve compared to the conventional surface acoustic wave filter.

In FIG. 4, C_{CON}, shown by a dotted line, represents a frequency response curve of the surface acoustic wave filter designed with the conventional surface acoustic wave resonator, and C_{INV}, shown as a solid line, represents a frequency response curve of the surface acoustic wave filter designed with the surface acoustic wave resonator according to the present invention.

As shown in FIG. 4, it can be seen that the upper limit of the curve C_{CON} of the conventional surface acoustic wave filter is P_{CON} while the upper limit of the curve C_{INV} of the surface acoustic wave filter according to the present invention is raised to P_{INV}. That is, the surface acoustic wave filter designed with the surface acoustic wave resonator according to the present invention may obtain a gain equal to the difference between P_{CON} and P_{INV}, whereby it is possible to reduce the insertion loss accordingly.

In other words, in the case of the conventional surface acoustic wave filter, a signal that has passed through the band is lost up to P_{CON}, whereas in the surface acoustic wave filter according to the present invention, a signal that has passed through the band is lost only up to P_{INV}. In the surface acoustic wave filter according to the present invention, therefore, loss corresponding to the difference between P_{CON} and P_{INV} is reduced, which shows that the surface acoustic wave filter according to the present invention has reduced insertion loss compared to the conventional surface acoustic wave filter.

Meanwhile, in FIGS. 5 and 6, S_{CON}, shown by a dotted line, represents a stop band frequency curve of the conventional surface acoustic wave filter, and S_{INV}, shown by a solid line, represents a stop band frequency curve of the surface acoustic wave filter according to the present invention.

From the measurement results of the conventional surface acoustic wave filter and the surface acoustic wave filter according to the present invention shown in FIGS. 5 and 6, it can be seen that the conventional surface acoustic wave filter has a fairly large width of the signal in the stop band and generates severe ripple while, in the surface acoustic wave filter of the present invention, the signal is stably attenuated in the same stop band and ripple is significantly reduced.

As described above, in the present invention, the configuration using a reflector designed as a single electrically connected mass in the conventional surface acoustic wave resonator is improved, wherein the reflection unit that reflects the surface acoustic wave generated from the IDT electrode unit is configured to include a plurality of reflectors that are electrically separated from each other and have different aperture lengths, thereby reducing the insertion loss in the pass band according to the frequency response, improving the attenuation characteristics in the stop band, and reducing ripple in the stop band, compared to the conventional surface acoustic wave filter.

### Industrial Applicability

The surface acoustic wave resonator according to the present invention has industrial applicability in the technical field of digital wireless communication devices such as smartphones, tablets, and personal portable terminals, and parts of communication-based equipment, such as GPS modules, Bluetooth modules, and digital TVs.

1. A surface acoustic wave resonator comprising:
a piezoelectric substrate;
an IDT electrode unit provided on the piezoelectric substrate, the IDT electrode unit being configured to perform at least one of conversion of an electrical signal into a surface acoustic wave on the piezoelectric substrate and conversion of the surface acoustic wave into an electrical signal;
a reflection unit disposed in a propagation direction of the surface acoustic wave generated from the IDT electrode unit, the reflection unit being configured to reflect the surface acoustic wave to the IDT electrode unit, wherein
the reflection unit comprises a plurality of electrically separated reflectors having different aperture lengths.

2. The surface acoustic wave resonator according to claim 1, wherein the reflection unit comprises:
a first reflection unit disposed on the piezoelectric substrate at one end of the IDT electrode unit, the first reflection unit comprising a plurality of reflectors having different aperture lengths; and
a second reflection unit disposed on the piezoelectric substrate at the other end of the IDT electrode unit, the second reflection unit comprising a plurality of reflectors having different aperture lengths.

3. The surface acoustic wave resonator according to claim 2, wherein the IDT electrode unit comprises at least one of:
a one-port IDT electrode having a plurality of input fingers and a plurality of output fingers; and
a two-port IDT electrode comprising an input IDT electrode and an output IDT electrode disposed spaced apart from each other by a predetermined distance.

4. The surface acoustic wave resonator according to claim 2, wherein
the first reflection unit comprises:
a first main reflector disposed adjacent to the one end of the IDT electrode unit, the first main reflector having the same aperture length as the IDT electrode unit, the first main reflector being configured to reflect the surface acoustic wave from the IDT electrode unit to the IDT electrode unit; and
at least one first sub-reflector disposed behind the first main reflector, the at least one first sub-reflector having a smaller aperture length than the first main reflector, and
the second reflection unit comprises:
a second main reflector disposed adjacent to the other end of the IDT electrode unit, the second main reflector having the same aperture length as the IDT electrode unit, the second main reflector being configured to reflect the surface acoustic wave from the IDT electrode unit to the IDT electrode unit; and
at least one second sub-reflector disposed behind the second main reflector, the at least one second sub-reflector having a smaller aperture length than the second main reflector.

5. The surface acoustic wave resonator according to claim 2, wherein
the first reflection unit comprises:
a first main reflector disposed adjacent to the one end of the IDT electrode unit, the first main reflector being configured to reflect the surface acoustic wave from the IDT electrode unit to the IDT electrode unit, the first main reflector being electrically grounded; and
at least one first sub-reflector disposed behind the first main reflector, the at least one first sub-reflector being electrically separated from the first main reflector, and
the second reflection unit comprises:
a second main reflector disposed adjacent to the other end of the IDT electrode unit, the second main reflector being configured to reflect the surface acoustic wave from the IDT electrode unit to the IDT electrode unit, the second main reflector being electrically grounded; and
at least one second sub-reflector disposed behind the second main reflector, the at least one second sub-reflector being electrically separated from the second main reflector.

6. The surface acoustic wave resonator according to claim 4, wherein
the first main reflector and the first sub-reflector of the first reflection unit are electrically separated from each other while the first main reflector is electrically grounded, and
the second main reflector and the second sub-reflector of the second reflection unit are electrically separated from each other while the second main reflector is electrically grounded.

7. The surface acoustic wave resonator according to claim 4, wherein the first sub-reflector and the second sub-reflector have the same aperture length or different aperture lengths.

8. The surface acoustic wave resonator according to claim 1, wherein the aperture length of the reflector disposed on the piezoelectric substrate at an end thereof in the propagation direction of the surface acoustic wave toward one side of the IDT electrode unit and the aperture length of the reflector disposed on the piezoelectric substrate at an end thereof in the propagation direction of the surface acoustic wave toward the other side of the IDT electrode unit are different from each other.

9. The surface acoustic wave resonator according to claim 5, wherein the first sub-reflector and the second sub-reflector have the same aperture length or different aperture lengths.
